(19) United States
(12) Patent Application Publication
(10) Pub. No.: US 2011/0024829 A1
(43) Pub. Date: Feb. 3, 2011

(54) SEMICONDUCTOR DEVICE HAVING VOIDS ALONG BURIED GATES AND METHOD FOR MANUFACTURING THE SAME

(75) Inventor: Sang Ho Lee, Gyeonggi-do (KR)

Correspondence Address: LADAS & PARRY LLP, 224 SOUTH MICHIGAN AVENUE, SUITE 1600, CHICAGO, IL, 60604, US

(73) Assignee: HYNIX SEMICONDUCTOR INC., Gyeonggi-do (KR)

(21) Appl. No.: 12/639,193

(22) Filed: Dec. 16, 2009

(30) Foreign Application Priority Data
Jul. 30, 2009 (KR) 10-2009-0070035

(51) Int. Cl. H01L 29/78; H01L 21/28

(52) U.S. Cl. 257/330; 438/589; 257/E21.158; 257/E29.262

(57) ABSTRACT

A semiconductor device having voids along buried gates and a method of manufacturing the same is presented. The semiconductor device includes recesses, a first gate electrode, a second gate electrode, and a gate protection layer. The first gate electrode fills in a lower portion of the recess. The second gate electrode is formed on the first gate electrode and partially fills in the upper portion of the recess such that the second gate electrode has a downwardly tapered width. The gate protection layer fills in the remaining portion of the recess while leaving voids next to the second gate electrode. Accordingly, it is thought that the voids reduce gate resistance and improve the gate-induced drain leakage (GIDL) characteristics of the resultant device.

### CROSS-REFERENCE TO RELATED APPLICATION

Priority to Korean patent application number 10-2009-0070035, filed on Jul. 30, 2009, which is incorporated by reference in its entirety, is claimed

### BACKGROUND OF THE INVENTION

The present invention relates to a semiconductor device and a method for manufacturing the same.

Semiconductor memory devices are devices that store data or information, such as program commands, and are chiefly classified into dynamic random access memory (DRAM) and SRAM (static RAM). DRAM memories can be store or read information into them. Although is information can be read from or written into DRAM, if information is not periodically written into DRAM within a certain period of time during the supply of power, contents stored in DRAM are lost. Even though DRAM must be continuously refreshed, DRAMS enjoy wide usage because they provide high-capacity memories along with being inexpensive, i.e., cheap per memory cell, and can be high integrated.

A metal-oxide semiconductor field effect transistor (hereinafter referred to as “MOSFET”) that is chiefly used in memory, such as in DRAMs, or can be used as in a logic device. The structure of the MOSFET may have a gate oxide layer, a polysilicon layer, a gate metal layer, and a gate hard mask layer deposited over a semiconductor substrate and a gate that is then stacked thereon by using a mask/etch process, thereby forming a channel in the MOSFET.

If a semiconductor device having a general structure is reduced in size, the length of a channel is shortened. If the channel length is shortened, a short channel effect and a gate induced drain leakage (GIDL) are likely to arise and consequently compromise the performance characteristics of the diminutive MOSFET. Gate channel lengths can be increased to address this problem. However, if the channel length is increased, another problem may arises which is related to the increased gate resistance.

### BRIEF SUMMARY OF THE INVENTION

Various embodiments of the invention are directed to providing a semiconductor device and a method for manufacturing the is same.

According to an aspect of the present invention, a method of manufacturing a semiconductor device comprises forming recesses in a semiconductor substrate, filling the recesses with first gate electrodes, respectively, forming sidewall spacers on the first gate electrode, forming a second gate electrode on the first gate electrode including the sidewall spacers, removing the sidewall spacers, and filling the recesses with a gate protection layer.

The forming-recesses-in-a-semiconductor-substrate preferably includes forming isolation layers defining an active region in the semiconductor substrate, performing ion implantation on the active region, and etching the active region.

The recesses preferably are etched 200 Å to 800 Å in depth from a surface of the semiconductor substrate.

A gate oxide layer preferably is further formed between the recess and the first gate electrode.

The first gate electrode preferably has a structure including titanium nitride (TiN) and tungsten (W).

The sidewall spacer preferably is made of nitride.

The sidewall spacer preferably is formed 50 Å to 300 Å in thickness.

The second gate electrode preferably is made of tungsten (W).

The gate protection layer preferably is formed of a capping nitride layer or a capping oxide layer

A gate electrode including the first gate electrode and the second gate electrode preferably has a [symbol] structure.

An upper region of the second gate electrode which does not come into contact with the first gate electrode preferably is wider than a lower region of the second gate electrode which comes into contact with the first gate electrode.

According to another aspect of the present invention, a semiconductor device comprises recesses formed by etching a semiconductor substrate, a first gate electrode filled within each of the recesses, a second gate electrode formed on the first gate electrode and configured to have a width smaller than a width of the first gate electrode, and a gate protection layer formed on the second gate electrodes.

The recesses preferably are etched 200 Å to 800 Å in depth from a surface of the semiconductor substrate.

A gate oxide layer preferably is further formed between the recess and the first gate electrode.

The first gate electrode preferably has a structure including titanium nitride (TiN) and tungsten (W).

The second gate electrode preferably is made of tungsten (W).

The gate protection layer preferably is formed of a capping nitride layer or a capping oxide layer.

A gate electrode including the first gate electrode and the second gate electrode preferably has a [symbol] structure.

An upper region of the second gate electrode which does not come into contact with the first gate electrode preferably is wider than a lower region of the second gate electrode which comes into contact with the first gate electrode.

### BRIEF DESCRIPTION OF THE DRAWINGS

FIGS. 1a to 1f are cross-sectional views illustrating a semiconductor device and a method for manufacturing the same according to an embodiment of the present invention.

### DESCRIPTION OF EMBODIMENT

Hereinafter, an embodiment of the present invention is described with reference to the accompanying drawings. It is understood herein that the drawings are not necessarily to scale and in some instances proportions may have been exaggerated in order to more clearly depict certain features of the invention.

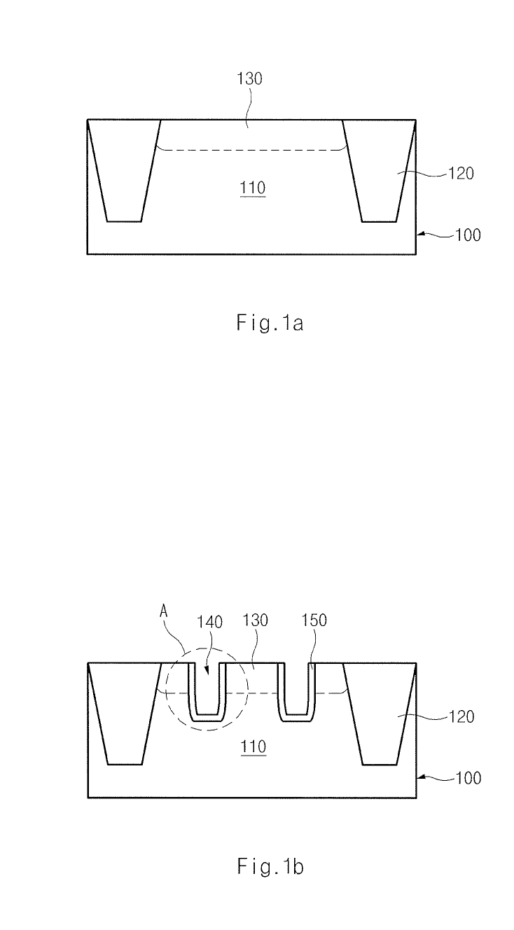

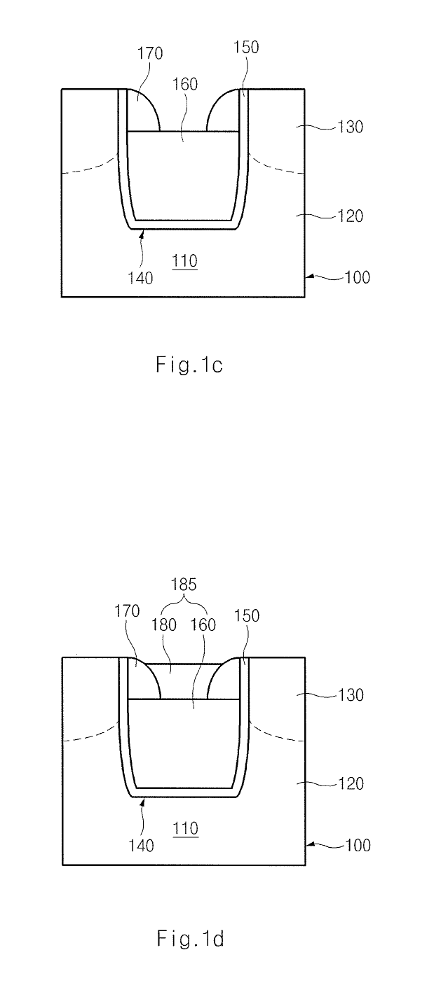

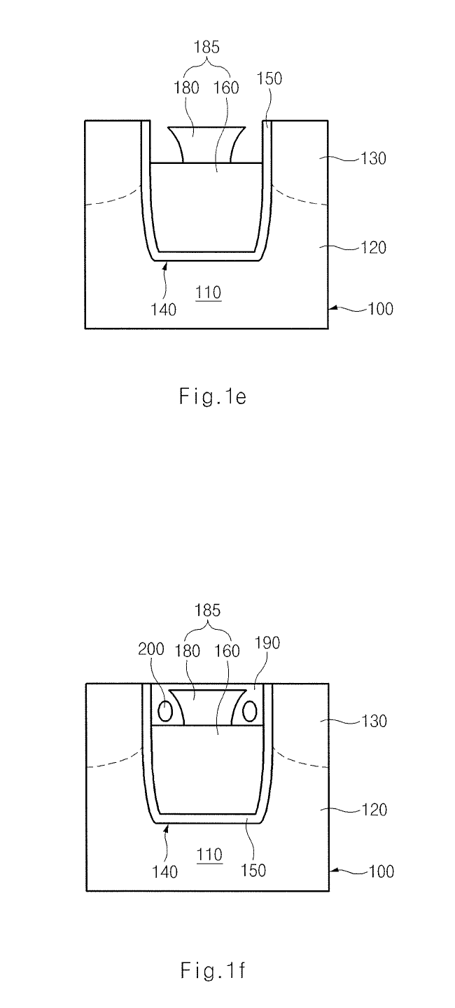

FIGS. 1a to 1f are cross-sectional views illustrating a semiconductor device and a method of manufacturing the same according to an embodiment of the present invention.

Referring to FIG. 1a, a semiconductor substrate 100 is etched to a specific depth, thereby forming trenches (not shown) in the semiconductor substrate. The trenches are filled with an insulating layer (not shown) to thereby form isolation layers 120 that are used to define an active region 110. In order to increase the size of the active region 110 and implement a high integration device, the isolation layers 120 preferably are formed using a shallow trench isolation (STI) process.

Ion implantation 130 is performed on the active region 110. The ion implantation 130 preferably is ion implantation for forming a well, a channel VT, and junctions.

Referring to FIG. 1b, a photoresist layer is formed on the entire surface including the active region 110. A photoresist pattern (not shown) is then formed by using any number of well known exposure and development processes that use a recess mask (not shown). Recesses 140 are formed by etching the active region 110 using the photoresist pattern as a mask. The recesses 140 preferably are etched 200 Å to 800 Å in depth from a surface of the semiconductor substrate 100. A gate oxide layer 150 is deposited on a surface of the recesses 140.

FIGS. 1c to 1f are enlarged diagrams of a region A shown in FIG. 1b.

Referring to FIG. 1c, a first gate electrode material (not shown) is deposited over the entire surface including the gate oxide layer 150. The first gate electrode material preferably comprises titanium nitride (TiN) and tungsten (W).

The first gate electrode material is etched back to form a first gate electrode 160 within the recess 140.

An insulating layer (not shown) is formed over the entire surface including the first gate electrodes 160. After forming a photoresist layer on the insulating layer, a photoresist pattern (not shown) is formed by is using any well known exposure and development processes that use a mask for spacers. Sidewall spacers 170 exposing the first gate electrode 160 are formed by etching the insulating layer (not shown) by using the photoresist pattern as a mask. The sidewall spacers 170 preferably are formed at a thickness of about 50 Å to 300 Å and are made of nitride.

Referring to FIG. 1d, a second gate electrode material (not shown) is further deposited over the entire surface including the exposed first gate electrodes 160. The second gate electrode material preferably comprises tungsten (W). The second gate electrode material is etched back until the sidewall spacers 170 are exposed, thereby forming a second gate electrode 180 within the recess.

Here, a gate electrode 185 including the first gate electrode 160 and the second gate electrode 180 has a [symbol] structure as depicted in FIG. 1d. Furthermore, an upper region (i.e., region opposite to a region coming into contact with the first gate electrode 160) of the second gate electrode 180 which does not come into contact with the first gate electrode 160 is wider than a lower region of the second gate electrode 180 which comes into contact with the first gate electrode 160. Accordingly, the second gate electrode 180 is downwardly tapered such that the lower region of the second gate electrode 180 thinner than the upper region the second gate electrode 180 due to being formed around the upwardly tapered sidewall spacers 170.

Referring to FIGS. 1e and 1f, the sidewall spacers 170 are is subsequently removed using a wet etch process. A gate protection layer 190 is then deposited over the entire surface including the second gate electrodes 180. The gate protection layer 190 is then subsequently etched to expose the active region 110 and the gate oxide layers 150.

The gate protection layer 190 preferably is formed of a capping nitride layer or a capping oxide layer. When etching the gate protection layer 190, an etchback process or a chemical mechanical polishing process may be performed. In this case, buried voids 200 are generated in a region of the recess 140 in which the gate protection layer 190 is filled because of the downwardly tapered width structure of the second gate electrode 180. The buried voids 200 function to reduce the generation of an electric field, thereby improving the gate-induced drain leakage (GIDL) characteristic. Accordingly, the refresh characteristic of a semiconductor device can be improved.

As described above, according to the present invention, when forming burial gate electrodes, the first gate electrode is formed within the recess, the sidewall spacers are formed on the first gate electrode, the second gate electrode is formed over the entire surface including the sidewall spacers, and the sidewall spacers are then removed. Accordingly, gate resistance can be reduced. Further, the GIDL characteristic can be improved by voids generated when depositing the nitride layer for protecting the gate electrodes on the region from which the sidewall spacers have been removed. Consequently, there is an advantage in that the refresh characteristic of a semiconductor device can be improved.

The above embodiment of the present invention is illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device, the method comprising:
forming recesses in a semiconductor substrate;
filling the recesses with first gate electrodes;
forming sidewall spacers on the first gate electrode and on sides of the recesses;
forming a second gate electrode on the first gate electrode in the recess and on the sidewall spacers in the recess;
removing the sidewall spacers; and
filling the recesses with a gate protection layer to form voids next to the second gate electrode.

2. The method according to claim 1, wherein the forming the is recesses in the semiconductor substrate includes:
forming isolation layers defining an active region in the semiconductor substrate;
performing ion implantation on the active region; and
etching the active region.

3. The method according to claim 1, wherein the first gate electrode comprises titanium nitride (TiN) and tungsten (W).

4. The method according to claim 1, wherein the sidewall spacers comprise nitride or oxide.

5. The method according to claim 1, wherein the second gate electrode comprises tungsten (W) or aluminum (Al).

6. The method according to claim 1, wherein the gate protection layer is comprises a capping nitride layer or a capping oxide layer.

7. The method according to claim 1, wherein a gate electrode including the first gate electrode and the second gate electrode has a [symbol] structure.

8. The method according to claim 1, wherein an upper region of the second gate electrode which does not come into contact with the first gate electrode is wider than a lower region of the second gate electrode which comes into contact with the first gate electrode.

9. The method according to claim 1, wherein voids are buried within the gate protection layer.

10. A semiconductor device, comprising:
recesses formed by etching a semiconductor substrate;
a first gate electrode filled within each of the recesses;
a second gate electrode formed on the first gate electrode and configured to have a width smaller than a width of the first gate electrode; and
a gate protection layer formed on the second gate electrodes having voids next to the second gate electrode.

11. The semiconductor device according to claim 10, wherein the first gate electrode comprises titanium nitride (TiN) and tungsten (W).

12. The semiconductor device according to claim 10, wherein the second gate electrode comprises tungsten (W) or aluminum (Al).

13. The semiconductor device according to claim 10, wherein the gate protection layer is formed of a capping nitride layer or a capping is oxide layer.

14. The semiconductor device according to claim 10, wherein a gate electrode including the first gate electrode and the second gate electrode has a [symbol] structure.

15. The semiconductor device according to claim 10, wherein an upper region of the second gate electrode which does not come into contact with the first gate electrode is wider than a lower region of the second gate electrode which comes into contact with the first gate electrode.

16. The semiconductor device according to claim 10, wherein voids are formed within the gate protection layer are buried.
